(19) United States
(12) Patent Application Publication
(10) Pub. No.: US 2014/0111956 A1
(43) Pub. Date: Apr. 24, 2014

(54) JOINING METHOD USING METAL FOAM, METHOD OF MANUFACTURING SEMICONDUCTOR DEVICE, AND SEMICONDUCTOR DEVICE

(71) Applicant: FUJI ELECTRIC CO., LTD., Kawasaki-shi (JP)

(72) Inventor: Katsumi TANIGUCHI, Matsumoto-city (JP)

(73) Assignee: FUJI ELECTRIC CO., LTD., Kawasaki-shi (JP)

(21) Appl. No.: 14/022,367

(22) Filed: Sep. 10, 2013

(30) Foreign Application Priority Data
Oct. 18, 2012 (JP) 2012-230627
Dec. 19, 2012 (JP) 2012-277172

(51) Int. Cl. H01L 23/00; B23K 35/02

(52) U.S. Cl. CPC H01L 24/89; B23K 35/0233; H01L 24/10
USPC 361/771; 228/249; 228/203; 228/194

(57) ABSTRACT

A joining method using a metal foam, a method of manufacturing a semiconductor device by using the joining method, and a semiconductor device produced by the manufacturing method are disclosed. A metal foam body is sandwiched between members to be joined, which are then brought into contact with each other and subjected to heat treatment. In this heat treatment, films of low-melting-point metal, such as Sn films covering the members to be joined, are melted. An alloy layer—an intermetallic compound—is formed by bringing about solid-liquid diffusion of Cu of a skeleton of open cells of the metal foam body in the molten Sn. At this stage, a Cu skeleton is left in the metal foam body. Highly thermally resistant and highly reliable joining can be realized by joining the members to be joined together by using this alloy layer.

### BACKGROUND OF THE INVENTION

A. Field of the Invention

The present invention relates to a joining method using metal foam, a method of manufacturing a semiconductor device such as a power semiconductor module in use of the joining method, and a semiconductor device produced by this manufacturing method.

B. Description of the Related Art

FIG. 9 is a cross-sectional diagram showing substantial parts of a conventional power semiconductor module. This power semiconductor module is mounted with a power semiconductor element such as an insulated gate bipolar transistor (IGBT).

This power semiconductor module is configured by joining semiconductor chip 13 to insulating substrate 10, with solder member 23 therebetween, insulating substrate 10 being configured by a ceramic substrate and a conductor pattern (metal foil 12). The ceramic substrate contains aluminum oxide, aluminum nitride, silicon nitride and the like as base compounds. The conductor pattern is configured by metal foil 12 of Cu (copper) or Al (aluminum). Semiconductor chip 13 has a single crystal Si (silicon) or SiC (silicon carbide) as its substrate.

Solder member 23 should not be melted or deteriorated by heat generated by the power semiconductor element. A high-temperature solder member having a Pb-rich composition, such as Pb-5Sn (melting point: 310° C.) or Pb-10Sn (melting point: 275° C.), is used as solder member 23. The chemical symbol Pb represents lead, and Sn represents tin. Due to its high ductility, such Pb-rich solder is used, for example, to reduce the thermal expansion difference between semiconductor chip 13 formed by a silicon substrate and the metal foil 12 of Cu on insulating substrate 10 having a conductor pattern thereon. Therefore, a highly reliable joint can be obtained.

Japanese Patent Application Publication No. 2008-28295 and Japanese Patent Application Publication No. 2008-235898 describe joining methods that do not perform solder joining. In these methods, thin films of Sn, Cu, Ag (silver) and the like with low melting points are stacked on a joint portion, which is then heated at a temperature higher than the lowest melting point of any of the thin films, and then a load is applied to the joined surfaces to cause solid-liquid diffusion in the stacked films. These patent documents describe solid-liquid diffusion joining for forming a stable intermetallic compound having a high melting point, such as Cu₆Sn₅, Cu₃Sn, or Ag₃Sn.

Japanese Patent Application Publication No. 2004-298962 discloses a power module substrate that implements joining by using a solder joining member which is obtained by saturating a metal foam body with solder beforehand.

Japanese Patent Application Publication No. 2008-311273 discloses a joining body having a layer which is obtained by saturating upper and lower surfaces of a plate-like metal porous body with the brazing filler metal, and a semiconductor module that is obtained by joining an element and a substrate to each other by means of the joining body.

Japanese Patent Application Publication No. 2008-200728 discloses an example of a semiconductor module that uses a solder member and a Ni (nickel) coated metal foam body.

### SUMMARY OF THE INVENTION

A power semiconductor module is required to tolerate temperatures equal to or higher than 250° C. in consideration of a reflow step in which the module assembly is heated, and heat generated by its semiconductor chip. For this reason, high-temperature solder members with Pb-rich compositions are used in a joint portion between an insulating substrate having conductor patterns thereon and a rear surface of the semiconductor chip, and in a joint portion between a front surface of the semiconductor chip and an electric wiring member such as a lead frame. However, the use of Pb is regulated in some regions on account of its harmful impact on the environment.

A Sn—Ag-based solder member, a Sn—Cu-based solder member, a Sn—Ag—Cu-based solder member and the like are standardized as a solder member without Pb. However, these solder members are used in low-temperature regions and medium-temperature regions and are not sufficiently heat resistant. An ongoing study of high-temperature Pb-free solder shows some advantages and disadvantages thereof; hence, at this moment, an effective solder material is not selected.

A joining method in which solder joining is not adopted has been studied. In such a method, thin films of Sn, Cu, Ag and the like with low melting points are stacked on a joint portion, which is then heated at temperature higher than the lowest melting point of any of the thin films, and then solid-liquid diffusion is caused in the stacked films, to form a stable intermetallic compound having a high melting point. However, the speed of solid-liquid diffusion is normally low, and solid-liquid diffusion takes long time. Therefore, the joining temperature needs to be raised, which makes the resultant intermetallic compound hard and fragile.

The thicknesses of the stacked films can be reduced in order to reduce the time required for solid-liquid diffusion, which makes the joined layers thin. In order to evenly adhere the surfaces to be joined to each other, the surfaces to be joined need to be extremely flat.

Due to the thermal expansion difference between the semiconductor chip and the metal foil of the insulating substrate, stress is generated as a result of an increase in the temperature during a heat cycle test (H/C) or power cycle test (P/C), causing cracks.

Japanese Patent Application Publication No. 2008-28295 and Japanese Patent Application Publication No. 2008-235898 do not describe the use of a metal foam body to join the members together.

Moreover, according to Japanese Patent Application Publication No. 2004-298962, Japanese Patent Application Publication No 2008-311273, and Japanese Patent Application Publication No. 2008-200728, the metal foam is saturated with a solder material or brazing filler metal to obtain a joining material, and the members thereof are joined together not by using an alloy layer formed by solid-liquid diffusion, but by using the solder material or brazing filler metal.

In addition, regarding joining the members together by using a metal foam body, Japanese Patent Application Publication No 2004-298962, Japanese Patent Application Publication No. 2008-311273, and Japanese Patent Application Publication No. 2008-200728 neither disclose nor suggest (1) continuation of diffusion until a low-melting-point metal layer dissolves in a heat treatment for joining the members, (2) forming Sn plating or Au plating on the metal foam body, and (3) forming a Ni-based metalized layer on the rear surface of the power semiconductor chip and forming a Ti layer on the underlayer of the Ni-based metalized layer.

The present invention provides a joining method using a metal foam, which is capable of accomplishing highly thermally resistant and highly reliable joining, a method of manufacturing a semiconductor device by using the joining method, and a semiconductor device produced by the manufacturing method.

The present invention described in the main claim provides a joining method using a metal foam, the method having the steps of: sandwiching a porous metal foam body between two members to be joined, the opposing surfaces of which are coated with low-melting-point metal layers respectively, the porous metal foam body being configured by open cells and a skeleton thereof; bringing the metal foam body into contact with the low-melting-point metal layers; executing a heat treatment to melt each of the low-melting-point metal layers; impregnating the open cells with the molten low-melting-point metal; forming an alloy layer, which is an intermetallic compound, by bringing about solid-liquid diffusion of metal configuring the skeleton, in the molten low-melting-point metal; joining the members to be joined together by using the alloy layer; and dissolving the layer of low-melting-point metal from joined surfaces of the members to be joined, to leave partially the metal configuring the skeleton of the open cells, in the form of a skeleton so that the metal does not form into the alloy layer.

In one aspect of the present invention, the metal foam body may be of three-dimensional network.

In another aspect of the present invention, a total volume of the open cells may account for 10% to 60% of the entire volume of the metal foam body.

In still another aspect of the present invention, the total volume of the open cells may account for 30% to 50% of the entire volume of the metal foam body.

In a further aspect of the present invention, the layer of low-melting-point metal may be formed of a Sn member and the skeleton of the metal foam body is formed of a Cu member.

In a still further aspect of the present invention, as an underlayer for the layer of low-melting-point metal, a Ni layer or a metalized layer obtained by adding phosphorus or boron to a Ni layer may be formed.

In another aspect of the present invention, a surface of the skeleton of the open cells of the metal foam body may be Sn-plated, or Ni-plated and then Au-plated.

In a further aspect of the present invention. Sn may be pressed into the open cells of the metal foam body to fill up the open cells.

In a still further aspect of the present invention, the heat treatment may be performed at 230° C. or higher to 400° C. or lower.

In another aspect of the present invention, the heat treatment may be performed while applying pressure to a contact surface between each of the members to be joined and the metal foam body.

In a further aspect of the present invention, the pressure may be 20 MPa or lower.

A still further aspect of the present invention is a method of manufacturing a semiconductor device by using the joining method using a metal foam according to any one of the claims, the manufacturing method having the steps of: depositing a Ni film on a conductor pattern of a insulating substrate and then depositing a Sn film thereon; stacking a Ti film, a Ni film, and a Sn film, in this order, on a metal electrode on a rear surface of a semiconductor chip; sandwiching the metal foam body made of Cu between the Sn film of the conductor pattern and the Sn film of the rear surface of the semiconductor chip, to bring these Sn films into contact with each other; and executing a heat treatment to melt the Sn films, impregnating the open cells of the metal foam body with the molten Sn, forming an alloy layer, which is an intermetallic compound, by bringing about solid-liquid diffusion of the Cu member of the skeleton of the open cells in the Sn member, dissolving the Sn films to leave partially the Cu member configuring the skeleton of the open cells of the metal foam body, in the form of a skeleton so that the Cu member does not form into the alloy layer, and joining the semiconductor chip and the conductor pattern to each other with the alloy layer therebetween.

A still further aspect of the above method of manufacturing a semiconductor device is a method of manufacturing a semiconductor device, having, subsequent to the implementation of the above method of manufacturing a semiconductor device, the steps of: depositing a Ni film onto a front surface electrode of the semiconductor chip and then depositing a Sn film thereon; depositing a Ni film on a connected conductor and then depositing a Sn film thereon; sandwiching the metal foam body between the semiconductor chip and the connected conductor to bring the semiconductor chip and the connected conductor into contact with each other; and executing a heat treatment to melt the Sn films, impregnating the open cells of the metal foam body with the molten Sn member, forming an alloy layer, which is an intermetallic compound, by bringing about solid-liquid diffusion of the Cu member of the skeleton of the open cells in the Sn member, dissolving the Sn films to leave some of the Cu member configuring the skeleton of the open cells of the metal foam body, in the form of a skeleton so that the Cu member does not form into the alloy layer, and joining the semiconductor chip and the connected conductor to each other with the alloy layer therebetween.

A still further aspect of the above method of manufacturing a semiconductor device is a method of manufacturing a semiconductor device includes the following steps prior to the heat treatment: a step of depositing a Ni film on a front surface electrode of the semiconductor chip and then depositing a Sn film thereon; a step of depositing a Ni film on a connected conductor and then depositing a Sn film thereon; and a step of sandwiching the metal foam body between the semiconductor chip and the connected conductor to bring the semiconductor chip and the connected conductor into contact with each other.

In a still further aspect of the above method of manufacturing a semiconductor device, the heat treatment may be executed while pressing the semiconductor chip against the insulating substrate.

In yet another aspect of the above method of manufacturing a semiconductor device, the heat treatment may be executed while pressing the connected conductor against the semiconductor chip.

In a further aspect of the above method of manufacturing a semiconductor device, the heat treatment may be executed while pressing the connected conductor against the semiconductor chip and pressing the semiconductor chip against the insulating substrate.

In any aspect of the above method of manufacturing a semiconductor device, the heat treatment may be performed at 230° C. or higher to 400° C. or lower for 30 seconds or more to 30 minutes or less.

In one aspect of the above method of manufacturing a semiconductor device, the heat treatment may be performed at 300° C. or higher to 350° C. or lower for 30 seconds or more to 5 minutes or less.

In another aspect of the above method of manufacturing a semiconductor device, the pressing may be performed with a pressure of 20 MPa or lower.

In one aspect of the above method of manufacturing a semiconductor device, the pressing may be performed with a pressure of 5 MPa or higher to 10 MPa or lower.

In another aspect of the above method of manufacturing a semiconductor device, the connected conductor may be in the form of a ribbon or lead frame.

One aspect of the above method of manufacturing a semiconductor device is a method of manufacturing a semiconductor device in which a rear surface of a semiconductor chip is disposed on one of Cu conductor patterns that are formed on both surfaces of an insulating substrate, the method having the steps of: joining, to one of the conductor patterns, a Cu metal foam sheet of three-dimensional network having open cells; inserting a Sn member between the metal foam sheet and the rear surface of the semiconductor chip; implementing heating at a temperature equal to or higher than a melting point of the Sn member; bringing about a diffusion reaction between the molten Sn member and the Cu member of the metal foam sheet to join the metal foam sheet and the rear surface of the semiconductor chip together; dissolving the inserted Sn member by the diffusion reaction; and forming a CuSn-based alloy and leaving a Cu skeleton of the metal foam sheet of three-dimensional network in a joining base material of the CuSn-based alloy.

One aspect of the above method of manufacturing a semiconductor device is a method of manufacturing a semiconductor device in which a Cu electric wiring member is disposed on a front surface of the semiconductor chip, the method having the steps of: joining, to the electric wiring member, a Cu metal foam sheet of three-dimensional network having open cells; inserting a Sn member between the metal foam sheet and the rear surface of the semiconductor chip; implementing heating at a temperature equal to or higher than a melting point of the Sn member; bringing about a diffusion reaction between the molten Sn member and the Cu of the metal foam sheet to join the metal foam sheet and the rear surface of the semiconductor chip together; dissolving the inserted Sn member by the diffusion reaction; and forming a CuSn-based alloy and leaving a Cu skeleton of the metal foam sheet of three-dimensional network in a joining base material of the CuSn-based alloy.

One aspect of the above method of manufacturing a semiconductor device is a electric wiring member may be in the form of a ribbon or lead frame.

In one aspect of the above method of manufacturing a semiconductor device, the conductor pattern and the metal foam sheet, or the electric wiring member and the metal foam sheet, may be heated or pressed against each other while being heated, and thereby joined directly to each other.

In one aspect of the above method of manufacturing a semiconductor device, the conductor pattern and the metal foam sheet, or the electric wiring member and the metal foam sheet, may be heated or pressed against each other while being heated, and thereby joined to each other by Cu particles.

In one aspect of the above method of manufacturing a semiconductor device, the conductor pattern and the metal foam sheet, or the electric wiring member and the metal foam sheet, may be joined to each other using a Ag-based or Cu-based brazing filler metal.

One aspect of the above method of manufacturing a semiconductor device is a method of manufacturing a semiconductor device in which a rear surface of a semiconductor chip is disposed on one of Cu conductor patterns that are formed on both surfaces of an insulating substrate and in which a Cu electric wiring member is disposed on a front surface of the semiconductor chip, the method having the steps of: joining, to one of the conductor patterns, a first Cu metal foam sheet of three-dimensional network having open cells, and joining, to the electric wiring member, a second Cu metal foam sheet of three-dimensional network having open cells; inserting a first Sn member between the first metal foam sheet and the rear surface of the semiconductor chip, and also inserting a second Sn member between the second metal foam sheet and the front surface of the semiconductor chip; implementing heating at temperatures equal to or higher than melting points of the first and second Sn members; bringing about a diffusion reaction between the first and second molten Sn members and the Cu members of the metal foam sheets, to join the metal foam sheets and the rear and front surfaces of the semiconductor chip together, respectively; dissolving the first and second inserted Sn members by the diffusion reaction; and forming a CuSn-based alloy and leaving a Cu skeleton of each of the metal foam sheets of three-dimensional network in a joining base material of the CuSn-based alloy.

In another aspect of the above method of manufacturing a semiconductor device, each of the metal foam sheets may be joined to the conductor pattern and the electric wiring member directly or by using Cu particles or brazing filler metal.

Any one the aspects of the above method of manufacturing a semiconductor device is a semiconductor device that is produced by the method of manufacturing a semiconductor device described in any one of the claims.

According to the present invention, a metal foam body is sandwiched between members to be joined. The members to be joined are brought into contact with each other and heated. In this heat treatment, a Sn film or other film of low-melting-point metal that covers the members to be joined is melted. Solid-liquid diffusion of Cu configuring the skeleton of the open cells of the metal foam body is caused in the molten Sn, to form an alloy layer, which is an intermetallic compound. At this stage, a Cu skeleton is left in the metal foam body. Then, the members to be joined are joined to each other by this alloy layer, achieving highly thermally resistant and highly reliable joining. With this joining method, a highly thermally resistant and highly reliable semiconductor device can be produced.

Furthermore, a semiconductor device of higher thermal resistant and reliability can be obtained by joining, directly or using brazing filler metal or Cu particles (nanoparticles), a surface on the opposite side to the surface facing a semiconductor chip, which is one of the members to be joined of the metal foam body, to the other one of the members to be joined, such as a lead frame and an insulating substrate with conductor patterns.

### BRIEF DESCRIPTION OF THE DRAWINGS

The foregoing advantages and features of the invention will become apparent upon reference to the following detailed description and the accompanying drawings, of which:

FIGS. 1A to 1C are cross-sectional diagrams sequentially showing main steps A to C of a joining method using a metal foam according to a first example of the present invention;

FIGS. 2A and 2B are partially enlarged views of FIG. 1, wherein FIG. 2A is an enlarged view of a part A of FIG. 1B and FIG. 2B is an enlarged view of a part B of FIG. 1C;

FIG. 3 is a cross-sectional diagram showing main steps of a joining method using a metal foam according to a second example of the present invention;

FIG. 4 is a cross-sectional diagram showing main steps of a joining method using a metal foam according to a third example of the present invention;

FIGS. 5A and 5B are cross-sectional diagrams sequentially showing main production steps A and B of a method of manufacturing a semiconductor device according to a fourth example of the present invention;

FIGS. 6A to 6E are explanatory diagrams showing in detail the production steps of FIG. 5, wherein FIGS. 6A to 6E are cross-sectional diagrams sequentially showing main steps of the manufacturing method;

FIGS. 7A to 7C are cross-sectional diagrams sequentially showing main production steps A to C of a method of manufacturing a semiconductor device according to a fifth example of the present invention;

FIGS. 8A to 8C are cross-sectional diagrams sequentially showing main production steps A to C of a method of manufacturing a semiconductor device according to a sixth example of the present invention;

FIG. 9 is a cross-sectional diagram showing substantial parts of a conventional power semiconductor module;

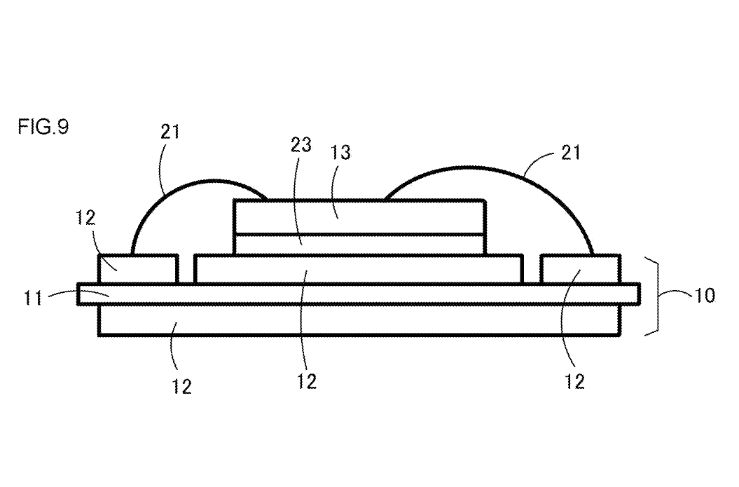

FIGS. 10A to 10C are cross-sectional diagrams showing main steps of a method of manufacturing a semiconductor device according to a seventh example of the present invention;

FIGS. 11D to 11F are cross-sectional diagrams showing main steps of a method of manufacturing the semiconductor device according to the seventh example of the present invention, the main steps following the steps shown in FIG. 10;

FIGS. 12A to 12C are cross-sectional diagrams showing main steps of a method of manufacturing a semiconductor device according to an eighth example of the present invention; and

FIGS. 13D to 13F are cross-sectional diagrams showing main steps of a method of manufacturing the semiconductor device according to the eighth example of the present invention, the main steps following the steps shown in FIG. 12.

### DETAILED DESCRIPTION OF SPECIFIC EMBODIMENTS

Embodiments of the present invention are now described hereinafter with examples. The same reference numerals denote the same conventional parts. A metal foam body described hereinafter means a three-dimensional network configured by open cells and a skeleton. The three-dimensional network also includes a mesh structure.

The open cells mentioned above are a type of cells wherein normal tiny closed cells are connected to each other, but walls therebetween remain and form a skeleton of the cell. Closed cells, on the other hand, are closed tiny hollows surrounded by walls. The open cells, therefore, are hollows formed by the tiny hollows connected to each other.

### EXAMPLE 1

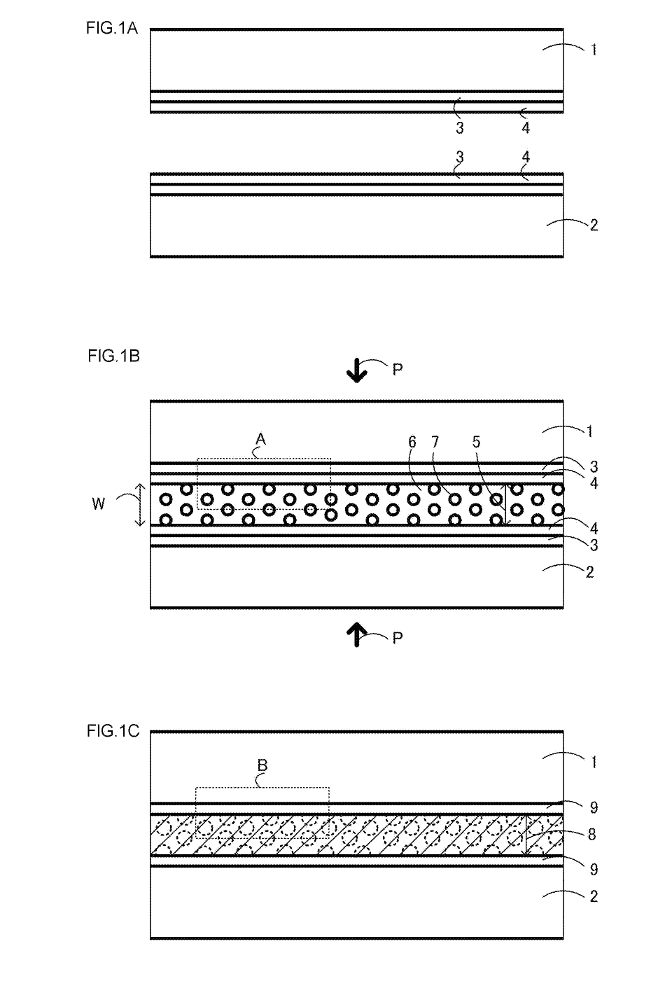

FIGS. 1A to 1C are cross-sectional diagrams sequentially showing main steps of a joining method using a metal foam according to a first example of the present invention.

In FIG. 1A, two Cu members to be joined 1, 2 are prepared. Ni film 3 is deposited onto each of the members to be joined 1, 2. Sn film 4 is then deposited thereon.

In FIG. 1B, Cu metal foam body 5 is placed between the two members to be joined 1, 2. The members to be joined 1, 2 are applied with pressure P and brought into contact with each other.

In FIG. 1C, the joined members are heated under pressure P in incubator 6 to melt the Sn of the members to be joined 1, 2 and solid-liquid diffuse the Cu of skeleton 7 of open cells 6 of metal foam body 5 in the Sn. This solid-liquid diffusion forms CuSn alloy layer 8 which is a metal compound. At this stage, Sn films 4 and Ni films 3 each form NiSn alloy layers 9 as intermetallic compounds. Due to slow reactions of the NiSn alloy layers 9, Ni films 3 may remain in the form of underlayers. The members to be joined 1, 2 are joined to each other by CuSn alloy layer 8 and NiSn alloy layers 9.

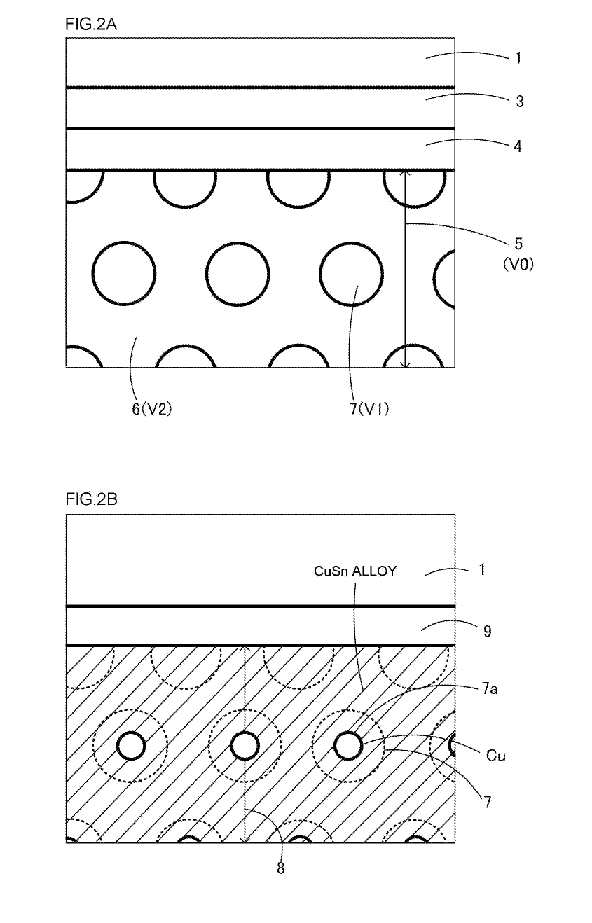

FIG. 2A and FIG. 2B are partially enlarged views of FIGS. 1B and 1C, with FIG. 2A being an enlarged view of a part A of FIG. 1B and FIG. 2B being an enlarged view of a part B of FIG. 1C.

In FIGS. 1 and 2, the open cells of the metal foam body are impregnated with the molten Sn, and the Cu of skeleton 7 of open cells 6 is sold-liquid diffused in the molten Sn. This solid-liquid diffusion forms CuSn alloy layer 8 and NiSn alloy layers 9, which are intermetallic compounds. The Sn of Sn films 4 dissolves from the joined surfaces. The excess molten Sn may be pushed out of the joined surfaces by the pressure P and remains around the joined surfaces. At this stage, not entire skeleton 7 of open cells 6 turns into CuSn alloy layer 8, but Cu skeleton 7a (where copper is connected instead of forming particles) remains. In this state, open cells 6 have no Sn but include CuSn alloy layer 8 formed as a result of solid-liquid diffusion, and pure Cu skeleton 7a remains in CuSn alloy layers 8.

The average size of open cells 6 (the average width between skeleton 7) is several μm to several tens μm. Open cells 6 are impregnated with the Sn. Open cells 6 of metal foam body 5 between the joined members are covered with CuSn alloy layer 8. Pure Cu skeleton 7a, which does not form into alloy layer 8, remains in the form of a mesh in alloy layer 8.

For example, when the average diameter of open cells 6 is 30 μm and the average diameter of Cu skeleton 7 surrounding is 50 μm, the average width of skeleton 7a with pure Cu remaining therein can be 10 μm or more in terms of its cross section.

The thickness W of metal foam body 5 is approximately 0.03 mm to 0.2 mm. When the thickness is less than 0.03 mm, sufficiently large open cells cannot be formed. However, a thickness over 0.2 mm is so thick that a thermal resistance increases. It is preferred that the thickness W be approximately 0.05 mm to 0.1 mm. The heat treatment temperature is set to 23020 C. or higher to 400° C. or lower. A heat treatment temperature less than 230° C. cannot melt the Sn sufficiently, lowering the speed of solid-liquid diffusion. However, the heat treatment temperature exceeding 400° C. increases thermal residual stress, causing thermal deterioration in the members to be joined. A heat treatment temperature of 300° C. or higher to 350° C. or lower is preferred in order to manufacture a semiconductor device.

The total volume V of open cells 6 of metal foam body 5 is set to 10% or more to 60% or less with respect to the entire volume VO of metal foam body 5. This value (%) is obtained in the following formula: (Volume V0 of metal foam body 5−Volume V1 of the skeleton 7)/Volume V0 of metal foam body 5×100 (%). The total volume V of open cells 6 is calculated as follows: Volume V0 of metal foam body 5−Volume V1 of skeleton 7=Total volume V of open cells 6. When the total volume V of open cells 6 is less than 10%, the volume V1 of skeleton 7 increases, lowering its cushioning effect and deteriorating the adhesion to the unevenness of the members to be joined 1, 2. When the total volume V of open cells 6 is greater than 60%, the volume of Cu in decreases, and most of skeleton 7 forms into CuSn alloy layers 8 due to the reaction between the reduced Cu and the Sn. As a result, there remains almost no Cu skeleton 7a. Because the thermal resistance of CuSn alloy layer 8 is greater than that of the Cu, skeleton 7 lacking Cu causes an increase in the thermal resistance of metal foam body 5. Because the hardness of each CuSn alloy layer 8 is greater than that of the Cu, high hardness of CuSn alloy layer 8 cannot serve a cushioning function. For this reason, it is more preferred that the total volume V of open cells 6 be set to 30% or more to 50% or less.

In terms of the hardness and thermal resistance, it is preferred that the ratio of the total volume V of open cells 6 be set to 10% or more to 60% or less, as described above.

Depositing Sn films 4 on Ni films 3 of the members to be joined 1, 2 makes it easy for a Kirkendall void to be formed in the Cu of the members to be joined 1, 2 by solid-liquid diffusion when Sn is directly formed in the Cu of the members to be joined 1, 2. Then, by interposing a metalized layer of each Ni film 3 between the Cu of each of the members to be joined 1, 2 and the corresponding Sn film 4 (interface), the interface forms into the NiSn alloy layer 9, which is a NiSn intermetallic compound with low growth rate. Formation of the NiSn alloy layer 9 can prevent a Kirkendall void from being formed in the Cu of each of the members to be joined 1, 2. If a Kirkendall void is formed, it causes cracks, resulting in less reliable joining between the members to be joined 1, 2.

As described above, Sn that is melted in open cells 6 penetrates into the Cu metal foam body 5 of three-dimensional network having open cells 6. Because the surface area of skeleton 7 of open cells 6 is extremely greater than that of a flat plate, the speed of solid-liquid diffusion of the Cu of skeleton 7 into the molten Sn becomes extremely high. Thus, solid-liquid diffusion can be completed within a short period of time.

By leaving Cu skeleton 7 in metal foam body 5 having a three-dimensional network, an effect of reducing stress can be accomplished. In addition, even when cracks are generated due to the formation of a Kirkendall void, development of the cracks can be prevented in skeleton 7a. Because Cu skeleton 7 of metal foam body 5 extends from the joined surface of the member to be joined 1 to the member to be joined 2 through Cu skeleton 7a, joining the members to be joined 1, 2 to each other can provide excellent thermal conductivity and electrical conductivity.

Even when the joined surfaces of the members to be joined 1, 2 have a great degree of unevenness or warpage, the flexible metal foam body 5 and the members to be joined 1, 2 can make favorable contact with each other as a result of the application of a load to each member to be joined, without polishing the joined surfaces. Consequently, the members to be joined 1, 2 can be joined to each other favorably.

The present joining method does not use Pb and therefore serves as an alternative for a high-temperature Pb-free solder joining method. Use of the present joining method can achieve highly thermally resistant and reliable joining.

Note in this example that Ni films 3 are deposited on the Cu members to be joined 1, 2, and then Sn films 4 are deposited thereon. However, after depositing Ni films 3 on the Cu members to be joined 1, 2 and then depositing Au films thereon, Sn films 4 may be deposited on the Au films. Furthermore, the members to be joined 1, 2 may be made not only of Cu but also for example, of Al (with an Ni film as an underlayer). In such a case as well, Sn films 4 are deposited on the outermost surfaces of the members to be joined.

The material of metal foam body 5 is usually Cu, but Ni or Ag might be used.

### EXAMPLE 2

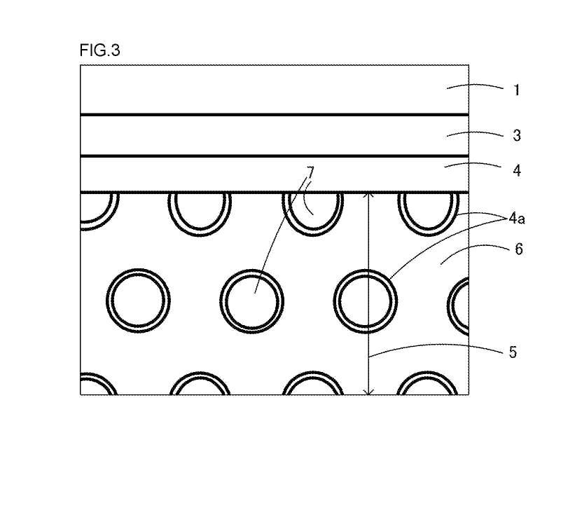

FIG. 3 is a cross-sectional diagram showing main steps of a joining method using a metal foam according to a second example of the present invention. The difference with FIG. 1 is that Sn film 4a is formed on skeleton 7 of Cu metal foam body 5. Sn film 4a may be formed by wet plating. When Sn film 4a is deposited on Cu skeleton 7 of open cells 6, Sn films 4 on the members to be joined 1, 2 and Sn film 4a on skeleton 7 melt and fuse together. When skeleton 7 is made of pure Cu, wettability of the Sn to the pure Cu becomes an issue; however, such an issue can be resolved. As a result, the Cu of metal foam body 5 can easily solid-liquid diffuse in the molten Sn of the members to be joined 1, 2, and consequently the Cu and the Sn react at a high speed, reducing the heat treatment time.

Of course, even when a Au film is formed in place of Sn film 4a by wet plating, wettability of Au can be improved, and the same effect can be accomplished thereby.

### EXAMPLE 3

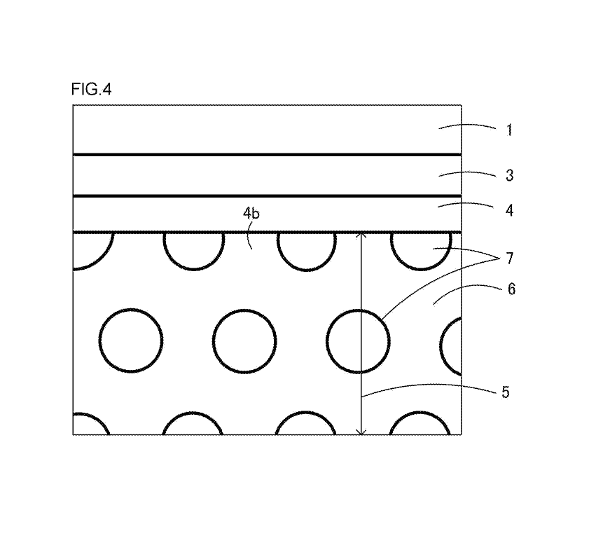

FIG. 4 is a cross-sectional diagram showing main steps of a joining method using a metal foam according to a third example of the present invention.

The difference between FIG. 1 and FIG. 3 is that Cu metal foam body 5 of this example is filled with Sn4b. The Sn4b is softened in open cells 6 by raising a temperature in advance near the melting (190° C.) point of the Sn4b and injected into open cells 6 of metal foam body 5.

At the stage of injecting the Sn4B into Cu metal foam body 5, the Cu and Sn4b in metal foam body 5 are simply in contact with each other without causing solid-liquid diffusion. Sn4b-filled Cu metal foam body 5 is held between the members to be joined 1, 2 covered by Sn films 4 and heated under the pressure P, to cause solid-liquid diffusion between the Sn4b and Cu, thereby joining the members to be joined 1, 2 together, with metal foam body 5 therebetween. In this case as well, the Sn of Sn films 4 on the members to be joined 1, 2 dissolves from the joined surfaces, leaving some of the Cu of skeleton 7 of open cells 6. Heat treatment conditions here are the same as those described in the previous example. Due to the presence of the Sn4b in open cells 6, the thickness of Sn films 4 deposited on the members to be joined 1, 2 may be reduced.

In each of the joining methods using metal foam as described in Examples 1 to 3, CuSn alloy layer 8, the intermetallic compound, is formed by solid-liquid diffusing the Cu in the molten Sn, and the members to be joined 1, 2 are joined to each other with CuSn alloy layer 8 therebetween. Some of the Cu of skeleton 7a remains in metal foam body 5. After the Sn dissolves from the joined surfaces, the Sn does not exist alone in the joint. Therefore, unlike a conventional joining method, a solder member or brazing filler metal is not added to the metal foam body.

Japanese Patent Application Publication No. 2004-298962 describes saturating a metal foam body with solder, in which case, as well, Sn is included therein. In this case, however, the joining materials are solder, and the joint contains Sn, Pb, Ag and the like. Thus, the method described in Japanese Patent Application Publication No. 2004-298962 is different from the method according to the present invention in which Sn simply penetrates into the metal foam body and then dissolves from the joined surfaces after the members to be joined are joined to each other.

### EXAMPLE 4

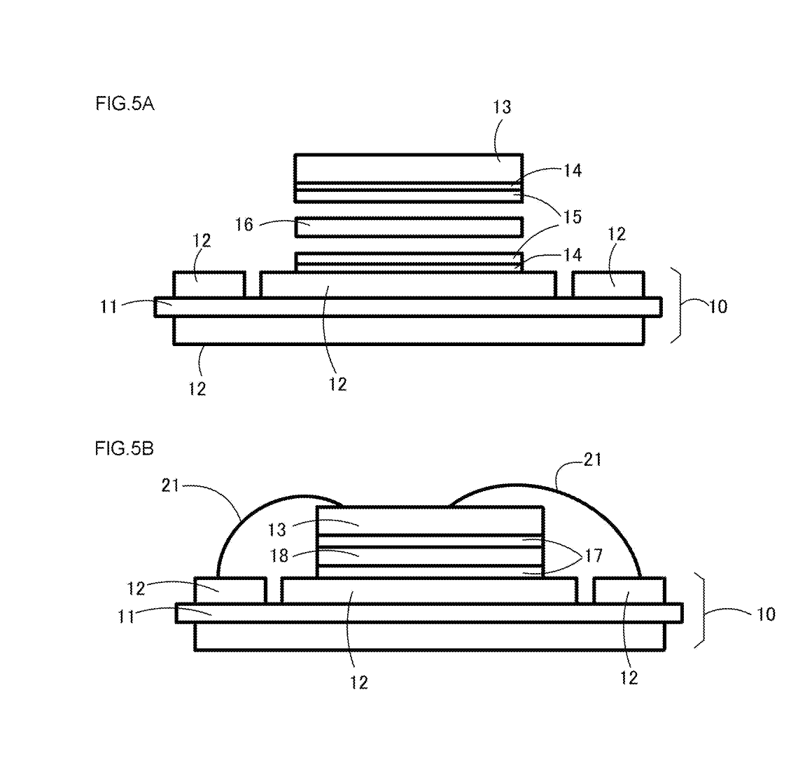

FIGS. 5A and 5B are cross-sectional diagrams sequentially showing main production steps of a method of manufacturing a semiconductor device according to a fourth example of the present invention. In this example, members to be joined are a back electrode of a semiconductor chip and a conductor pattern of an insulating substrate, respectively.

In the configuration shown in FIG. 5A, insulating substrate 10 is obtained by forming metal foil 12 of Cu or Al in a required pattern on both surfaces of ceramic substrate 11 containing aluminum oxide, aluminum nitride, silicon nitride and the like as base compounds. Semiconductor chip 13 of single crystal silicon or SiC is joined to a conductor pattern on one side of insulating substrate 10. In the present example, the conductor patterns formed on insulating substrate 10 are made of Cu; however, the material of the conductor patterns is not limited thereto.

On a surface to be joined of a Cu pattern on insulating substrate 10 to which semiconductor chip 13 is joined, metalized layer 14 made of Ni or obtained by adding P or B to Ni is formed into a thickness of 0.1 μm to 5 μm by wet plating, sputtering, or vacuum deposition such as vapor deposition. Subsequently, on the front surface of Ni-based metalized layer 14, Sn film 15 is formed into a thickness of 0.1 μm to 5 μm by wet plating, sputtering, or vacuum deposition such as vapor deposition. Sn film 15 can be formed as an alloy film by adding, to Sn, a material not having a melting point of 400° C. or lower, in an amount that does not raise the melting point of Sn or lowers the strength of a compound with Ni or Cu. In this example, Ni metalized layer 14 is formed on the surface of the Cu pattern (metal foil 12) on insulating substrate 10, in order to prevent the formation and growth of a CuSn alloy layer on the interface between metalized layer 14 and the Cu pattern. In a case where a Sn member is directly formed on the Cu pattern, a Kirkendall void can easily be formed on the Cu patterns. However, as a result of forming Ni metalized layer 14 on the interface between the Cu and Sn, NiSn intermetallic compound layer 17 with low growth rate is formed on the interface, realizing the effect of preventing the formation of a Kirkendall void on the Cu pattern.

Next, in FIG. 5B, on a surface to be joined on the rear surface of semiconductor chip 13 of single crystal silicon or SiC is a Ti metalized layer or the like, not shown, which is formed as an ohmic joining layer/adhesion layer for semiconductor chip 13. On the front surface of semiconductor chip 13, Ni-based metalized layer 14 and Sn film 15 are formed in the same manner as the surface to be joined of the Cu pattern (metal foil 12) on insulating substrate 10.

Cu metal foam body 16 of three-dimensional network having open cells is inserted between the surface to be joined of the Cu pattern (metal foil 12) on insulating substrate 10 and the surface to be joined on the rear surface of semiconductor chip 13. Metal foam body 16 is formed into a thickness of 0.05 mm to 1 mm, and the total volume of pores of the open cells is 10% to 60% with respect to the entire volume of the metal foam body 16. The less the pores in the metal foam body, the lower the cushioning effect and adhesion to the unevenness of the surfaces to be joined. The more the pores, on the other hand, the lower the proportion of the Cu, and, as a result of reacting with the Sn, most of the Cu forms into a CuSn alloy layer 18, leaving no Cu skeletal shape.

The surface to be joined of the Cu pattern on insulating substrate 10, the Cu metal foam body 16 of three-dimensional network having Cu open cells, and the surface to be joined on the rear surface of semiconductor chip 13, are disposed in such a manner that these members come into contact with each other in this order, and heated in an inert atmosphere or reducing atmosphere at a temperature equal to or higher than the melting point of the Sn (230° C. or higher) but equal to or lower than 400° C., for 30 seconds to 30 minutes. Preferably, these members are heated at 250° C. to 350° C. When heating these members, applying a load (pressure P) of 0.1 to 10 MPa to the joined surfaces can not only form a NiSn intermetallic compound more speedily, but also prevent the formation of a void (Kirkendall void). When heating these members in an atmosphere, Au or Sn plating is previously formed into a thickness of 0.1 μm to 1 μm over metal foam body 16, so that favorable wettability of Sn film 15 in the open cells of metal foam body 16 can be obtained when Sn film 15 on the surface to be joined melts in the atmosphere.

In this manner, a highly thermally resistant joining body capable of reducing stress and providing excellent thermal conductivity and electrical conductivity can be obtained.

Subsequently, a gate electrode on the front surface of semiconductor chip 13 and electric wiring of the metal pattern on insulating substrate 10 are formed by bonding wire 21.

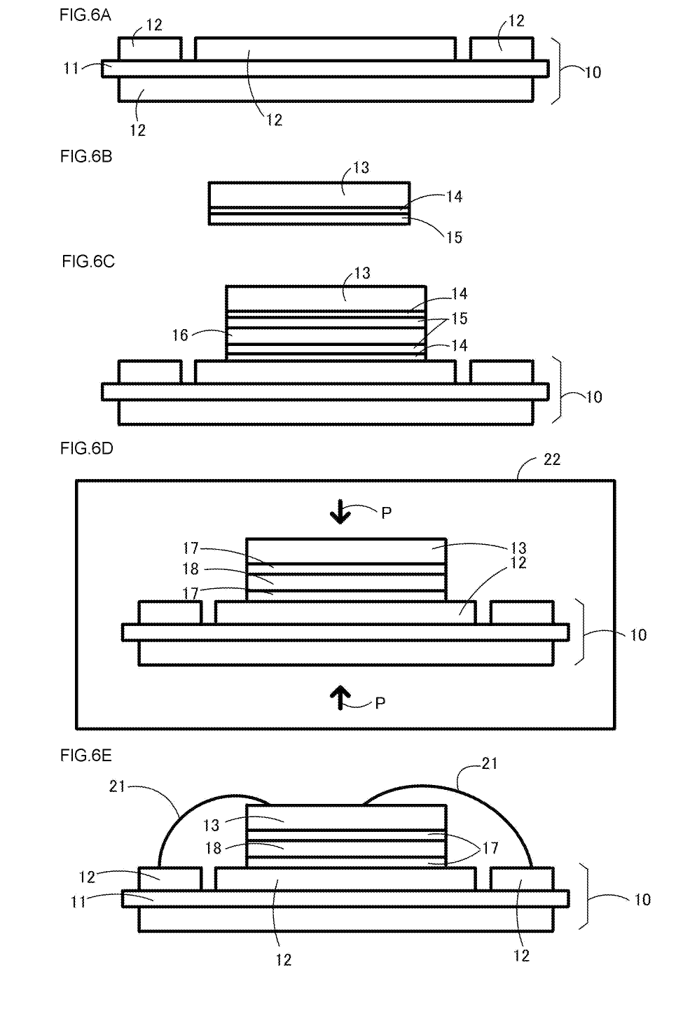

FIGS. 6A to 6E are explanatory diagrams showing in detail the production steps of FIG. 5, with these FIGS. 6A to 6E being cross-sectional diagrams sequentially showing main steps of the manufacturing method.

In FIG. 6A, metalized layer 14 made of Ni or obtained by adding P or B to Ni is deposited on conductor pattern 12 of insulating substrate 10, and then Sn film 15 is deposited thereon.

In FIG. 6B, a Ti film is deposited on an Al electrode, not shown, formed on the rear surface of semiconductor chip 13, and then metalized layer 14 is deposited on the Ti film. Sn film 15 is deposited on metalized layer 14.

In FIG. 6C, Cu metal foam body 16 is interposed between semiconductor chip 13 and insulating substrate 10, thereby bringing semiconductor chip 13 and insulating substrate 10 into contact with each other. When the rear surface of semiconductor chip 13, conductor pattern 12 on insulating substrate 10, and metal foam body 16 are in good contact with each other, pressure does not need to be applied to these members.

In FIG. 6D, under the pressure P in incubator 22, these members are heated at a predetermined temperature to melt the Sn, and the Cu of the skeleton of the open cells of metal foam body 16 is solid-liquid diffused in the molten Sn, to form CuSn alloy layer 18, an intermetallic compound. In so doing, as soon as Sn film 15 dissolves from the joined surfaces, some of the Cu of the skeleton of the open cells is left in metal foam body 16, and semiconductor chip 13 and conductor patterns 12 are joined to each other by CuSn alloy layer 18. At this stage, Ni(Cu)Sn alloy layer 17, an intermetallic compound, is configured by the Cu of metal foam body 16, Sn film 15, and Ni metalized layer 14.

In FIG. 6E, electric wiring between the unshown gate electrode on the front surface of semiconductor chip 13 and conductor pattern 12 on insulating substrate 10 has low current density, and is therefore formed with bonding wire 21 of Al, Cu, or Au.

### EXAMPLE 5

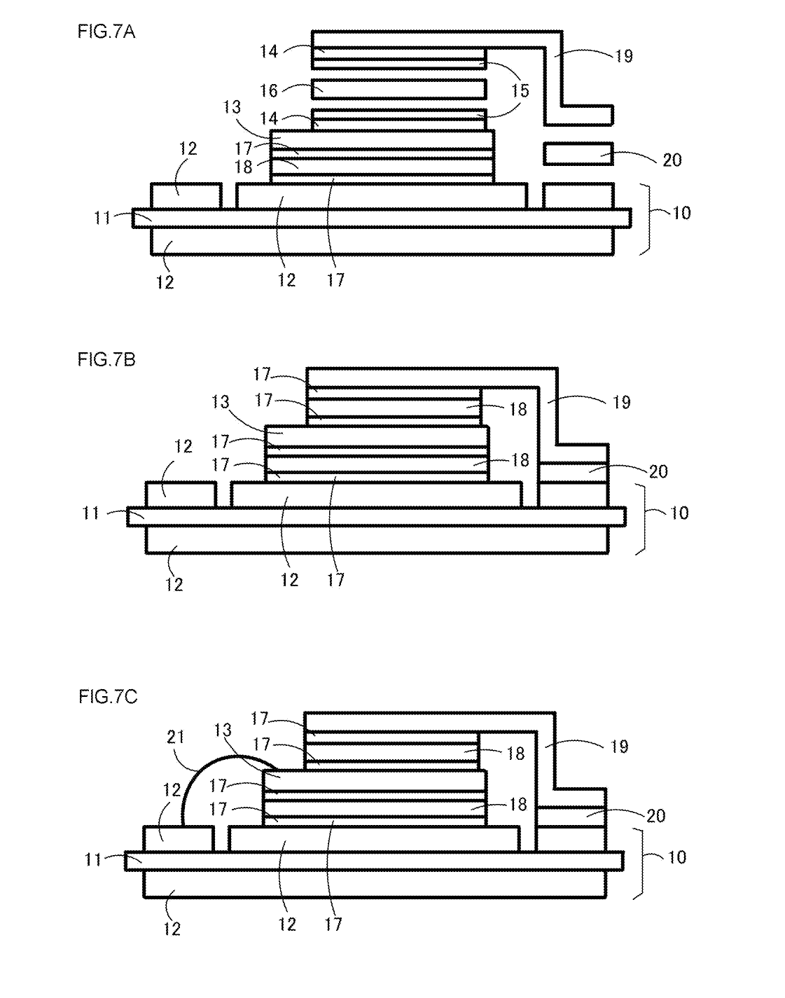

FIGS. 7A to 7C are cross-sectional diagrams sequentially showing main production steps A to C of a method of manufacturing a semiconductor device according to a fifth example of the present invention.

The difference between the manufacturing method shown in FIG. 7 and the manufacturing method shown in FIG. 4 is that after joining insulating substrate 10 and semiconductor chip 13 to each other by using metal foam body 16, the electric wiring members such as semiconductor chip 13 and lead frame 19 are joined together by metal foam body 16.

In FIG. 7A, insulating substrate 10 with Cu patterns thereon and the surface to be joined on the rear surface of semiconductor chip 13 are joined to each other by Cu metal foam body 16 of three-dimensional network having open cells. In this joint member, lead frame 19 or a ribbon-shaped electric wiring member made of Cu, Al, or other material having low electrical resistance and thermal resistance is joined to the electrode portion on the front surface of semiconductor chip 13. In this example, the electric wiring member is in the shape of Cu lead frame 19; however, the shape of the electric wiring member is not limited thereto.

An Al, Al—Si, or Al—Si—Cu electrode film is formed on the surface to be joined on the front surface of semiconductor chip 13. On the front surface of the electrode film, metalized layer 14 made of Ni or obtained by adding P or B to Ni is formed into a thickness of 0.1 μm to 5 μm by wet plating, sputtering, or vacuum deposition such as vapor deposition. Subsequently, on the front surface of Ni-based metalized layer 14, Sn film 15 is formed into a thickness of 0.1 μm to 5 μm by wet plating, sputtering, or vacuum deposition such as vapor deposition. Sn film 15 can be formed as an alloy film by adding, to Sn, a material not having a melting point of 400° C. or lower, in an amount that does not raise the melting point of Sn or lowers the strength of a compound with Ni or Cu.

Subsequently, as with the surface to be joined on the front surface of semiconductor chip 13, Ni-based metalized layer 14 and Sn film 15 are formed on a surface to be joined of Cu lead frame 19. When forming Ni-based metalized layer 14 and Sn film 15 only on the surface to be joined of Cu lead frame 19 by means of wet plating or impregnation, Ni metalized layer 14 and Sn film 15 may be formed over the entire lead frame 19.

Cu metal foam body 16 of three-dimensional network having open cells, which is inserted between the surface to be joined on the front surface of semiconductor chip 13 and the surface to be joined of the Cu lead frame 19, has the same configuration as the one described in Example 1.

Next in FIG. 7B, the surface to be joined on the front surface of semiconductor chip 13, Cu metal foam body 16 of three-dimensional network having open cells, and the surface to be joined of Cu lead frame 19, are disposed in such a manner that these members come into contact with each other in this order, and heated in an inert atmosphere or reducing atmosphere at a temperature equal to or higher than the melting point of Sn but equal to or lower than 400° C., for 30 seconds to 30 minutes. Preferably, these members are heated at 250° C. to 350° C. When heating these members, applying a load of 0.1 to 10 MPa to the joined surfaces can not only form an intermetallic compound more speedily, but also prevent the formation of a void. When heating these members in an atmosphere. Au or Sn plating is previously formed into a thickness of 0.1 μm to 1 μm over the metal foam body, so that favorable wettability of Sn film 15 in the cells of metal foam body 16 can be obtained when the Sn film 15 on the surface to be joined melts in the atmosphere. Cu lead frame 19 and the electrode of the metal pattern on insulating substrate 10 are joined to each other using high-temperature Pb-free solder 20. This joint portion is configured by joining the metallic members, wherein the expansion coefficient difference therebetween can be substantially ignored, and the temperature at this joint portion does not increase as much as that of semiconductor chip 13 does. For this reason, Sn-based, Bi-based, Au-based, or Zn-based high-temperature Pb-free solder can be used. However, it is necessary to select a solder material that can melt at the temperature at which the front surface of semiconductor chip 13 and lead frame 19 are joined and that is capable of soldering these members together.

Subsequently, as shown in FIG. 7C, electric wiring between the gate electrode on the front surface of semiconductor chip 13 and the electrode of the metal pattern on insulating substrate 10 has low current density, and is therefore formed with the bonding wire 21 of Al, Cu, or Au. However, when the heat of semiconductor chip 13 generates large stress between the front surface of semiconductor chip 13 and the material of bonding wire 21, semiconductor chip 13 and lead frame 19 can be joined to each other by metal foam body 16, in the same manner as the previous joining.

### EXAMPLE 6

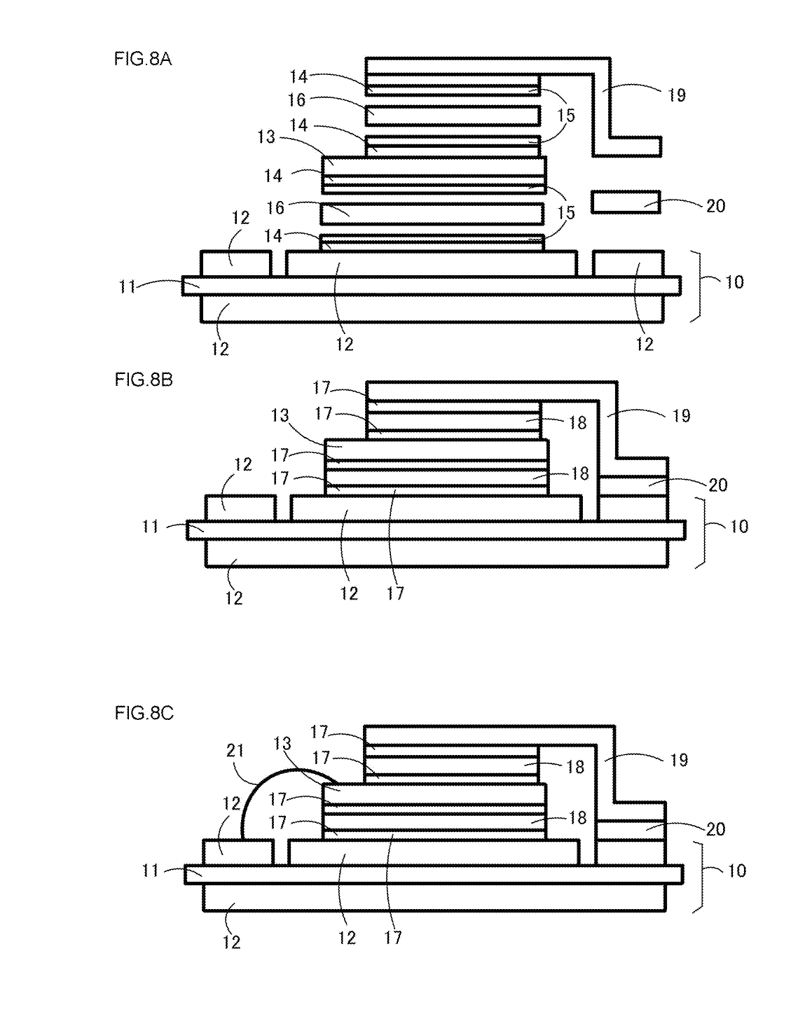

FIGS. 8A to 8C are cross-sectional diagrams sequentially showing main production steps A to C of a method of manufacturing a semiconductor device according to a sixth example of the present invention.

The difference between the manufacturing method shown in FIG. 8 and the manufacturing method shown in FIG. 7 is that the electric wiring members such as insulating substrate 10, semiconductor chip 13, and lead frame 19 are joined simultaneously by using metal foam bodies 16.

In FIG. 8A, insulating substrate 10 with metal patterns thereon, the rear surface of semiconductor chip 13, the front surface of semiconductor chip 13, and the lead frame 19, are bonded together simultaneously by using metal foam bodies 16. This requires less steps than those illustrated in FIG. 7. In so doing, the members to be supplied are the same as those shown in FIGS. 5 and 7. However, Ni metalized layer 14 and Sn film 15 can be formed on the surfaces to be joined on the front and rear surfaces of semiconductor chip 13 simultaneously.

Subsequently, in FIG. 8B, when insulating substrate 10 with the metal patterns thereon, the rear surface of semiconductor chip 13, the front surface of semiconductor chip 13, and lead frame 19 are joined together simultaneously by using metal foam bodies 16, the center of the surface to be joined on the front surface of semiconductor chip 13 to which lead frame 19 is joined is positioned in the vicinity of the center of the entire semiconductor chip 13. When the center of the surface to be joined on the front surface of semiconductor chip 13 does not match the center of the entire semiconductor chip 13, it results in application of a load to a surface opposite to the surface to be joined of lead frame 19, and the surfaces to be joined of semiconductor chip 13 and lead frame 19 cannot be joined parallel to the surface to be joined of insulating substrate 10, since a load, which is produced when implementing joining, is applied to a surface opposite to the surface to be joined of lead frame 19. In such a case, the joining layers have different thicknesses, resulting in inconsistent discharge characteristics or electrical characteristics, and hence inconsistency in the characteristics of the produced semiconductor device.

Cu metal foam bodies 16 of three-dimensional network having open cells are inserted between the surface to be joined of insulating substrate 10 having Ni metalized layer 14 and Sn film 15 and the surface to be joined on the rear surface of semiconductor chip 13 and between the surface to be joined on the front surface of semiconductor chip 13 and the surface to be joined of lead frame 19. These members are disposed in this order, in such a manner that these surfaces to be joined come into contact with each other, and are heated in an inert atmosphere or reducing atmosphere at a temperature equal to or higher than the melting point of Sn but equal to or lower than 400° C., for 30 seconds to 30 minutes. Preferably, these members are heated at 251° C. to 350° C. When heating these members. applying a load of 0.1 to 10 MPa to the front surface of semiconductor chip 13 and the surface to be joined of the lead frame 19 can not only form a metallic compound more speedily, but also prevent the formation of a void. At this stage, when this load is applied to insulating substrate 10 and the surface to be joined on the rear surface of semiconductor chip 13, the load applied to the front surface of semiconductor chip 13 increases, resulting in damage to semiconductor chip 13. When heating these members in an atmosphere, Au or Sn plating is previously formed into a thickness of 0.1 μm to 1 μm over metal foam body 16, so that favorable wettability of Sn film 15 in the open cells of metal foam body 16 can be obtained when Sn film 15 on the surface to be joined melts in the atmosphere. Cu lead frame 19 and the electrode of the metal pattern of insulating substrate 10 are joined to each other using high-temperature Pb-free solder 20. This joint portion is configured by joining the metallic members, wherein the expansion coefficient difference therebetween can be substantially ignored, and the temperature of this joint portion does not increase as much as that of semiconductor chip 13 does. For this reason, Sn-based, Bi-based, Au-based, or Zn-based high-temperature Pb-free solder can be used. However, it is necessary to select a solder material that can melt at the temperature at which the front surface of semiconductor chip 13 and lead frame 19 are joined to each other and that is capable of soldering these members together.

In this manner, a highly thermally resistant joining body capable of reducing stress and providing excellent thermal conductivity and electrical conductivity can be obtained.

Next, in FIG. 8C, the electric wiring between the gate electrode on the front surface of semiconductor chip 13 and the electrode of the metal pattern on insulating substrate 10 has low current density, and is therefore formed with bonding wire 21 of Al, Cu, or Au. However, when the heat of semiconductor chip 13 generates large stress between the front surface of semiconductor chip 13 and the material of bonding wire 21, insulating substrate 10, the rear surface of semiconductor chip 13, the front surface of semiconductor chip 13, and the lead frame can be joined together simultaneously by using metal foam bodies 16.

For the purpose of heat dissipation, in some cases a Cu or Al heat sink is provided on a metal pattern disposed on the side opposite to the metal pattern on insulating substrate 10 to which semiconductor chip 13 is joined. The method according to the present invention can be used for joining the heat sink to the insulating substrate.

In each of Examples 3 to 5 described above, due to the large surface area of the Cu metal foam body of three-dimensional network having open cells, the Sn is melted to impregnate the open cells of the metal foam body with the molten Sn. This process allows the solid-liquid diffusion reaction to be completed within a short period of time. Furthermore, by leaving the Cu skeleton in the metal foam body having a three-dimensional network, an effect of reducing stress can be accomplished. In addition, even when cracks are generated in the intermetallic compound, development of the cracks can be prevented. Because the Cu skeleton extends from the surface to be joined on the rear surface of the semiconductor chip to the surface to be joined of the insulating substrate having the conductor patterns thereon, the joining body with excellent thermal conductivity and electrical conductivity can be obtained.

Even when the surface to be joined of the insulating substrate having the conductor patterns thereon has a great degree of unevenness or warpage, the joined surfaces do not need to be polished, and the flexibility of the Cu metal foam body of three-dimensional network can deform the joined surfaces when load is applied parallel to the joined surfaces. Consequently, a joining body with good adhesion can be obtained.

The present joining method does not use Pb and therefore serves as an alternative for a high-temperature Pb-free solder joining method. Moreover, the present invention can achieve highly thermally resistant and reliable joining, as described above.

The semiconductor devices that are created by the manufacturing methods of Examples 4 to 6 are shown in FIGS. 5B, 7C, and 8C. In use of the joining method using metal foam body 5, a semiconductor device of high thermal resistance and reliability can be obtained.

The following Examples 7 to 9 are different from Examples 5 and 6 in that Examples 7 to 9 directly join metal foam body 16 (a Cu metal foam sheet 113) to be joined to semiconductor chip 13, to metal foil 12, 112 and lead frame 19 (an electric wiring member 118), or use metal particles or a brazing filler metal to join these members, metal foil 12, 112 being disposed on the side of metal foam body 16 that is opposite to the one joined to semiconductor chip 13.

### EXAMPLE 7

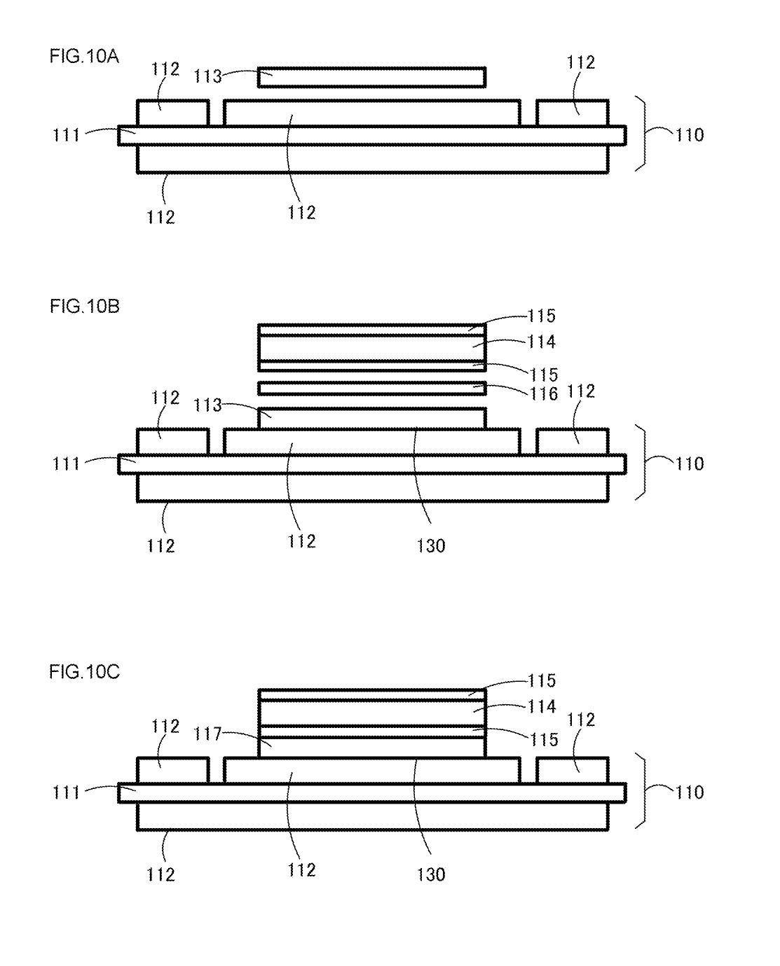

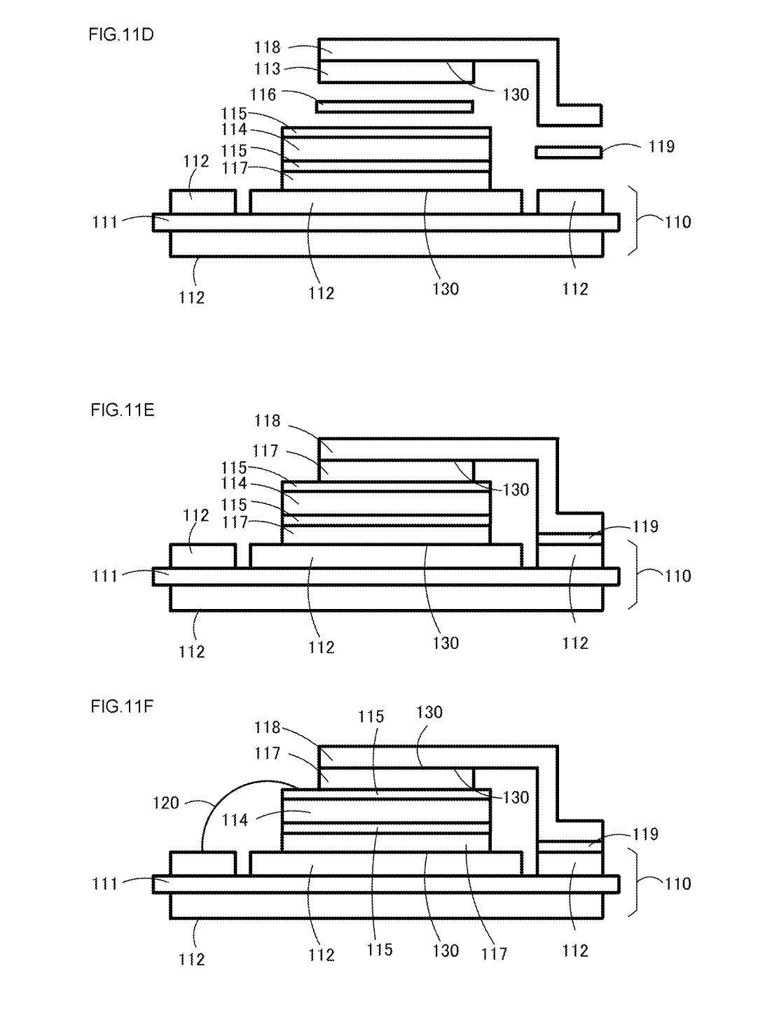

FIGS. 10 and 11 are each a cross-sectional diagram sequentially showing main steps of a method of manufacturing a semiconductor device according to a seventh example of the present invention.

In the configuration shown in FIG. 10A, insulating substrate 110 is obtained by forming metal foil 112 of Cu or Al in a required pattern on both surfaces of ceramic substrate 111 containing aluminum oxide, aluminum nitride, silicon nitride and the like as base compounds. Semiconductor chip 114 of single crystal silicon or SiC is joined to a conductor pattern on one side of insulating substrate 110. In the present invention, the conductor pattern formed on insulating substrate 110 is made of Cu; however, the material of the conductor pattern is not limited thereto.

Metal foam sheet 113 is bonded to the Cu pattern in a region, to which semiconductor chip 114 is joined, by direct joining 130. Metal foam sheet 113 is formed of Cu material and has a three-dimensional network having open cells with a thickness of 0.05 mm to 0.5 mm

Direct joining 130 is performed by bringing metal foam sheet 113 into direct contact with the surface to be joined of the Cu pattern on insulating substrate 110 to which semiconductor chip 114 is joined, and heating the resultant object in an inert atmosphere, a reducing atmosphere, or a vacuum atmosphere at 600° C. to 1100° C.

In so doing, when the surface of the Cu pattern on insulating substrate 110 has a great deal of roughness or poor flatness, a load of 0.1 MPa to 10 MPa is applied to metal foam sheet 113, thereby metal foam sheet 113 flexibly adheres to and is strongly joined to the surface of the Cu pattern on insulating substrate 110.

The load to be applied can be used to control the thickness of metal foam sheet 113 and the porosity of the open cells. The porosity of the open cells, after joining metal foam sheet 113 and insulating substrate 110 to each other, is preferably 50% or less with respect to the entire volume of metal foam sheet 113. When the porosity is high, the absolute amount of Cu drops. Consequently, CuSn alloy is generated as a result of a diffusion reaction between the Cu and the Sn-based material, resulting in elimination of the Cu skeleton of the three-dimensional network. However, when the porosity is low, closed-cell pores are formed easily and eventually remain in the form of voids, lowering the thermal conductivity and electrical conductivity of the semiconductor device.

Next, in FIG. 10B, Sn member 116 is disposed between metal foam sheet 113 and the rear surface of semiconductor chip 114. When a thickness of Sn member 116 is 10 pm or less, Sn member 116 can directly be formed on the surface to be joined of semiconductor chip 114 by means of wet plating, sputtering, or vacuum deposition such as vapor deposition. When a thickness of Sn member 116 is greater than 10 μm, Sn member 116 is dispensed in the form of paste or supplied in the form of foil or pellet.

In a case where Sn member 116 is added with another metal to have an alloy composition, the addition to Sn member 116 may be implemented as along as a material is used that does not have a melting point of 400° C. or lower in an addition amount that does not raise the melting point of Sn member 116 or lowers the strength of a compound with Ni or Cu.

It is also necessary to previously form metalized layer 115 made of Ni or obtained by adding P or B to Ni, on semiconductor chip 114, metalized layer 115 forming a reaction layer together with Sn member 116. In addition, a Ti metalized layer is formed beforehand on an underlayer of Ni-based metalized layer 115 in order to secure adhesion to semiconductor chip 114.

In a case where Sn member 116 is supplied in the form of paste, foil, or pellet, a Au metalized layer is formed in order to prevent oxidation of Ni-based metalized layer 115. A Ti layer and a Au layer are not shown in FIG. 10.

Next, in FIG. 10C, Cu metal foam sheet 113 of three-dimensional network having open cells, which is joined to the surface to be joined of the Cu pattern on insulating substrate 110, and the rear surface of semiconductor chip 114, are disposed in such a manner that these members come into contact with each other with Sn member 116 therebetween, and heated in an inert atmosphere, a reducing atmosphere, or a vacuum atmosphere at a temperature equal to or higher than the melting point of Sn member 116 but equal to or lower than 400° C., for 30 seconds to 30 minutes.

It is more preferred that the members be heated at 250° C. to 350° C. When heating these members, excessively supplied Sn member 116 is discharged from side surfaces of metal foam sheet 113 as a result of applying a load of 0.1 to 10 MPa to the joined surfaces. This can form a metallic compound more speedily and prevent the formation of a void. Consequently, joining body 117 having a melting point of 400° C. or higher can be obtained. Joining body 117 is configured by a three-dimensional network of a CuSn ahoy joining body obtained by soaking Sn member 116 in metal foam sheet 113, and a Cu skeleton having a three-dimensional network.

When heating these members in an atmosphere, Au or Sn plating is formed into a thickness of 0.01 μm to 0.5 μm in advance onto metal foam sheet 113. This enables to obtain permeability of metal foam sheet 113 with respect to the cells when Sn member 116 melts in the atmosphere.

Next, in FIGS. 11D and 11E, Cu metal foam sheet 113 of three-dimensional network having open cells is disposed on and joined to a surface to be joined of electric wiring member 118, which is also joined to the front surface of semiconductor chip 114, electric wiring member 118 being in the form of a Cu ribbon or lead frame. This joining is performed in the same manner as joining the Cu pattern on the insulating substrate 110 to metal foam sheet 113. An Al-based electrode film is formed on the front surface of semiconductor chip 114, and metalized layer 115 made of Ni or obtained by adding P or B to Ni is formed thereon by means of wet plating or the like. Metal foam sheet 113 joined to electric wiring member 118 and the front surface of semiconductor chip 114 are joined to each other by Sn member 116, as with the case where metal foam sheet 113 joined to the Cu pattern on insulating substrate 110 to the rear surface of semiconductor chip 114. Even when joining electric wiring member 118 to semiconductor chip 114 after joining the rear surface of semiconductor chip 114 to metal foam sheet 113 joined to the Cu pattern on insulating substrate 110, joining between electric wiring member 118 and semiconductor chip 114 can be accomplished favorably even when joining body 117 remelts, because joining body 117, joined previously, has a melting point of 400° C. or higher. Electric wiring member 118, semiconductor chip 114, and joining body 117 can be joined together simultaneously. When joining these members simultaneously, it is preferred that a pressure of 0.1 to 5 MPa be applied thereto, because the front surface of semiconductor chip 114 has a smaller joining area than the rear surface of the same does, and is not the center load of semiconductor chip 114.

For these reasons, the highly thermally resistant joining body 117 capable of reducing stress and providing excellent thermal conductivity and electrical conductivity can be obtained.

Subsequently, as shown in FIG. 11F, semiconductor chip 114 and metal foil 112 are connected to each other by bonding wire 120. These members are stored in a case, not shown, thereby completing a semiconductor device.

Because the metal foam sheet and the metal foil or electric wiring member 118 are adhered to each other by direct joining 130, this joining is stronger than when joining these members using CuSn alloy layer 18, enhancing the reliability of the semiconductor device.

### EXAMPLE 8

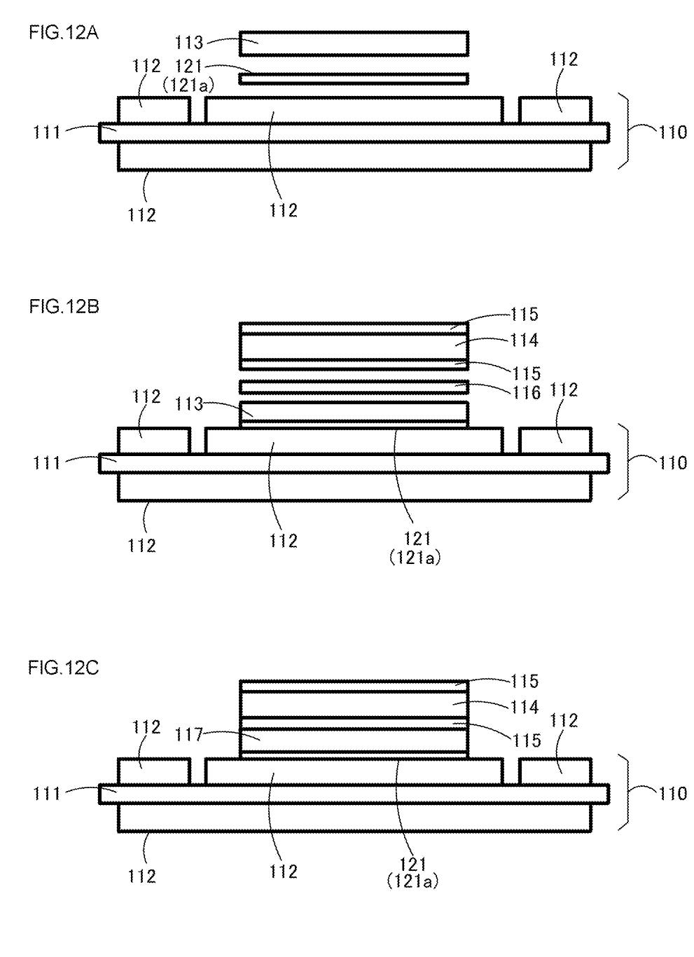

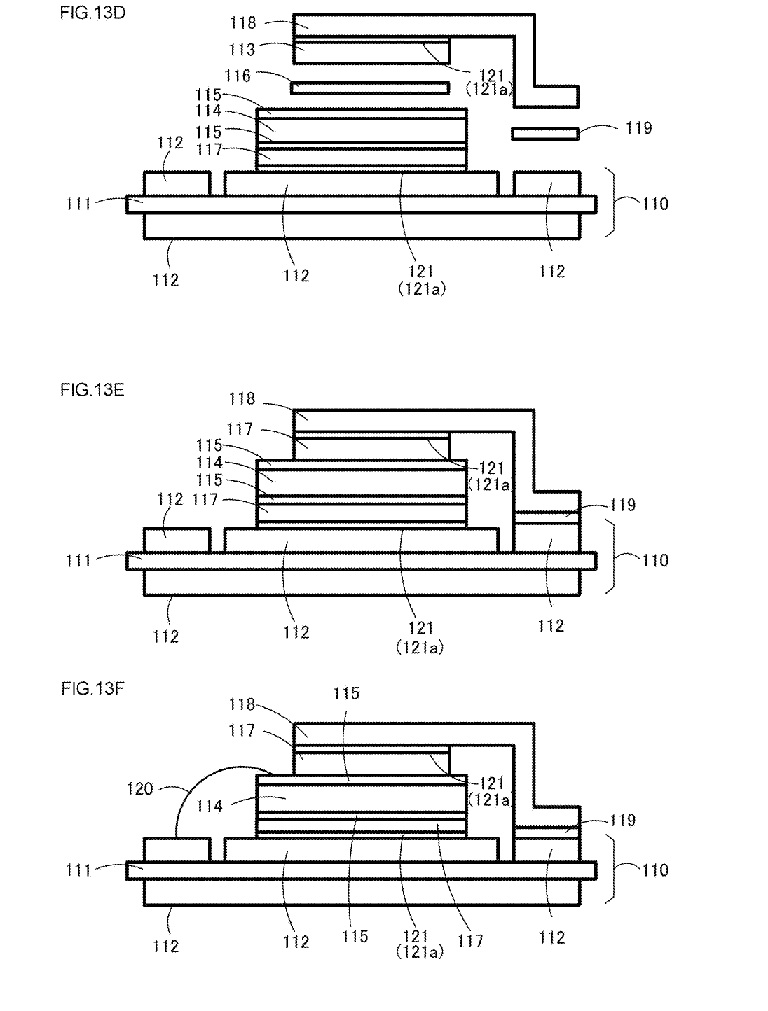

FIGS. 12 and 13 are each a cross-sectional diagram sequentially showing main steps of a method of manufacturing a semiconductor device according to an eighth example of the present invention. The difference with Example 7 is that the members are joined together using Cu particles 121 in place of direct joining 130.

As shown in FIG. 12A, the configurations of insulating substrate 110 having Cu patterns thereon, semiconductor chip 114, electric wiring member 118 in the form of a Cu ribbon or lead frame, and Cu metal foam sheet 113 of three-dimensional network having open cells, are the same as those described in Example 1.

Joining insulating substrate 110 having Cu patterns thereon to metal foam sheet 113 and electric wiring member 118 to metal foam sheet 113 shown in FIG. 13D is performed by inserting therebetween Cu particles 121 dispersed in volatile solvent in a thickness of 0.01 μm to 1 μm. In other words, taking advantage of the size of the Cu particles, the Cu particles can be sintered at low temperature lower than the melting point of bulk Cu. Cu particles 121 are metal nanoparticles and normally used in the form of paste.

Organic solvent and organic dispersant are mixed into the paste-like Cu particles 121, which is applied into a thickness of 10 μm to 50 μm on the surface to be joined of the Cu pattern of insulating substrate 110 and the surface to be joined of electric wiring member 118.

Next, as shown in FIG. 12B, metal foam sheet 113 is disposed in contact with the surface applied with Cu particles 121, and heated in an inert atmosphere, a reducing atmosphere, or a vacuum atmosphere at 300° C. to 600° C. for 1 minute to 60 minutes.

Next, in so doing, as shown in FIG. 12C, a pressure of 1 MPa to 10 MPa is applied to metal foam sheet 113 to volatilize the solvent or the dispersant and thereby causes a sintering action of Cu particles 121. As a result, insulating substrate 110 having Cu patterns therein and metal foam sheet 113 are strongly joined to each other.

The solvent having Cu particles 121 dispersed therein volatilizes by being heated at the time of joining these members. However, all the solvent scatters through the open cells of metal foam sheet 113, preventing the formation of unjoined portions such as voids. Cu particles 121 form into a sintered body, and the melting point thereof becomes equal to that of bulk Cu. Therefore, when metal foam sheet 113 and semiconductor chip 114 are joined to each other via Sn member 116 afterwards, the joint portion therebetween does not melt.

Subsequently, as shown in FIG. 13D, after electric wiring member 118 and metal foam sheet 113 are joined to each other by Cu particles 121, Sn member 116 is disposed between metal foam sheet 113 and semiconductor chip 114. Next, metal foam sheet 113 and semiconductor chip 114 are joined to each other, as shown in FIG. 13E. The joining conditions are as described above.

Semiconductor chip 114 and metal foil 112 are connected to each other by bonding wire 120, as shown in FIG. 13F. These members are stored in a case, not shown, thereby completing a semiconductor device.

In Example 7, direct joining is employed to join metal foam sheet 113, semiconductor chip 114, and electric wiring member 118. In Example 8, the Cu particles are used to join these members. However, Example 7 may adopt the Cu particles and Example 8 may adopt the direct joining.

Because the metal foam sheet and the metal foil or electric wiring member 118 are adhered to each other by Cu particles 121, this joining is stronger than when joining these members using CuSn alloy layer 18. Therefore, the reliability of the semiconductor device can be improved.

### EXAMPLE 9

A method of manufacturing a semiconductor device according to a ninth example of the present invention is now described. FIGS. 12 and 13 of Example 8 are used as a cross-sectional diagram showing main steps of this method of manufacturing a semiconductor device. The difference with Example 8 is that the members are joined together using brazing filler metal 121a in place of Cu particles 121.

The configurations of insulating substrate 110 having Cu patterns thereon, semiconductor chip 114, electric wiring member 118 in the form of a Cu ribbon or lead frame, and Cu metal foam sheet 113 of three-dimensional network having open cells, are the same as those described in Examples 1 to 7.

Brazing filler metal 121a, such as Ag-based brazing filler metal or Cu-based brazing filler metal, is used to join insulating substrate 110 having Cu patterns thereon to metal foam sheet 113 and to join electric wiring member 118 to metal foam sheet 113.

Brazing filler metal 121a is supplied in the form of pellet, in a thickness of 30 μm to 50 μm, onto the surface to be joined of the Cu pattern on insulating substrate 110 and the surface to be joined of electric wiring member 118. Metal foam sheet 113 is disposed on brazing filler metal 121a and heated in an inert atmosphere, a reducing atmosphere, or a vacuum atmosphere at 700° C. to 000° C.

When joining these members using brazing filler metal 121a, application of pressure thereto causes molten brazing filler metal 121a penetrate through the open cells of metal foam sheet 113, filling up the pores. Therefore, it is preferred that the thickness of the pellet-like brazing filler metal 121a be as thin as possible when supplying brazing filler metal 121a to the surface to be joined of the Cu pattern on insulating substrate 110 and the surface to be joined of electric wiring member 118.

However, when brazing filler metal 121a is thin, and the degrees of surface roughness and flatness of the surface to be joined of the Cu pattern on insulating substrate 110 and the surface to be joined of electric wiring member 118 are high, unjoined portions might be generated. Thus, a pressure of 1 MPa or lower is applied to these members.

Insulating substrate 110 to which metal foam sheet 113 is joined and semiconductor chip 114 are joined to each other in the same manner as Example 7, as well as semiconductor chip 114 and electric wiring member 118 to which metal foam sheet 113 is joined.

As described above, the same joining method is adopted in Examples 7 to 9 when joining insulating substrate 110 having the Cu patterns (metal foil 112) thereon, shown in FIGS. 10 to 13, to Cu metal foam sheet 113 of three-dimensional network having open cells, and when joining electric wiring member 118 in the form of a Cu ribbon or lead frame, to Cu metal foam sheet 113 of three-dimensional network having open cells. However, these members may be joined by different joining methods, as described above.

For instance, when Cu foil 12 configuring the Cu pattern of insulating substrate 110 is joined to ceramic substrate 111, which is the base material, by using brazing filler metal, it is preferred that insulating substrate 110 with the Cu pattern and metal foam sheet 113 be joined to each other using Cu particles 121 at low joining temperature, and that electric wiring member 118 and metal foam sheet 113 be joined to each other by means of direct joining in order to achieve a stronger joint therebetween.

Thus, a joining method using metal foam has been described according to the present invention. Many modifications and variations may be made to the techniques and structures described and illustrated herein without departing from the spirit and scope of the invention. Accordingly, it should be understood that the methods described herein are illustrative only and are not limiting upon the scope of the invention.

What is claimed is:

1. A joining method using a metal foam, the method comprising the steps of:
sandwiching a porous metal foam body between two members to be joined, the porous metal foam body comprising open cells and a skeleton thereof;
bringing the metal foam body into contact with a layer of low-melting-point metal that covers the members to be joined;
executing a heat treatment to melt the layer of low-melting-point metal;
impregnating the open cells with the molten low-melting-point metal;
forming an alloy layer, which is an intermetallic compound, by bringing about solid-liquid diffusion of metal configuring the skeleton, in the molten low-melting-point metal;
joining the members to be joined together by using the alloy layer; and
dissolving the layer of low-melting-point metal from joined surfaces of the members to be joined, to leave partially the metal configuring the skeleton of the open cells, in the form of a skeleton so that the metal does not form into the alloy layer.

2. The joining method using a metal foam according to claim 1, wherein the metal foam body is of three-dimensional network.

3. The joining method using a metal foam according to claim 1, wherein a total volume of the open cells is 10% to 60% of the entire volume of the metal foam body.

4. The joining method using a metal foam according to claim 3, wherein the total volume of the open cells is 30% to 50% of the entire volume of the metal foam body.

5. The joining method using a metal foam according to claim 1, wherein the layer of low-melting-point metal is formed of a Sn member and the skeleton of the metal foam body is formed of a Cu member.

6. The joining method using a metal foam according to claim 5, wherein, as an underlayer for the layer of low-melting-point metal, a Ni layer or a metalized layer obtained by adding phosphorus or boron to a Ni layer is formed.

7. The joining method using a metal foam according to claim 5, wherein a surface of the skeleton of the open cells of the metal foam body is Sn-plated, or Ni-plated and then Au-plated.

8. The joining method using a metal foam according to claim 5, wherein Sn is pressed into the open cells of the metal foam body to fill up the open cells.

9. The joining method using a metal foam according to claim 1, wherein the heat treatment is performed at 230° C. or higher to 400° C. or lower.

10. The joining method using a metal foam according to claim 1, wherein the heat treatment is performed while applying pressure to a contact surface between each of the members to be joined and the metal foam body.

11. The joining method using a metal foam according to claim 10, wherein the pressure is 20 MPa or lower.

12. A method of manufacturing a semiconductor device by using the joining method using a metal foam according to claim 1, the manufacturing method comprising the steps of:
depositing a Ni film on a conductor pattern of a insulating substrate and then depositing a Sn film thereon;
stacking a Ti film, a Ni film, and a Sn film, in this order, on a metal electrode on a rear surface of a semiconductor chip;
sandwiching the metal foam body made of Cu between the Sn film of the conductor pattern and the Sn film of the rear surface of the semiconductor chip, to bring these Sn films into contact with each other; and
executing a heat treatment to melt the Sn films, impregnating the open cells of the metal foam body with the molten Sn, forming an alloy layer, which is an intermetallic compound, by bringing about solid-liquid diffusion of Cu member of the skeleton of the open cells in the Sn member, dissolving the Sn films to leave partially the Cu member configuring the skeleton of the open cells of the metal foam body, in the form of a skeleton so that the Cu member does not form into the alloy layer, and joining the semiconductor chip and the conductor pattern to each other with the alloy layer therebetween.

13. A method of manufacturing a semiconductor device as claimed in claim 12, additionally comprising the steps of:
depositing a Ni film onto a front surface electrode of the semiconductor chip and then depositing a Sn film thereon;
depositing a Ni film on a connected conductor and then depositing a Sn film thereon;
sandwiching the metal foam body between the semiconductor chip and the connected conductor to bring the semiconductor chip and the connected conductor into contact with each other; and
executing a heat treatment to melt the Sn films, impregnating the open cells of the metal foam body with the molten Sn member, forming an alloy layer, which is an intermetallic compound, by bringing about solid-liquid diffusion of the Cu member of the skeleton of the open cells in the Sn member, dissolving the Sn films to leave partially the Cu member configuring the skeleton of the open cells of the metal foam body, in the form of a skeleton so that the Cu member does not form into the alloy layer, and joining the semiconductor chip and the connected conductor to each other with the alloy layer therebetween.

14. The method of manufacturing a semiconductor device according to claim 12, comprising, prior to the heat treatment:
a step of depositing a Ni film on a front surface electrode of the semiconductor chip and then depositing a Sn film thereon;
a step of depositing a Ni film on a connected conductor and then depositing a Sn film thereon; and
a step of sandwiching the metal foam body between the semiconductor chip and the connected conductor to bring the semiconductor chip and the connected conductor into contact with each other.

15. The method of manufacturing a semiconductor device according to claim 12, wherein the heat treatment is executed while pressing the semiconductor chip against the insulating substrate.

16. The method of manufacturing a semiconductor device according to claim 13, wherein the heat treatment is executed while pressing the connected conductor against the semiconductor chip.

17. The method of manufacturing a semiconductor device according to claim 14, wherein the heat treatment is executed while pressing the connected conductor against the semiconductor chip and pressing the semiconductor chip against the insulating substrate.

18. The method of manufacturing a semiconductor device according to claim 12, wherein the heat treatment is performed at 230° C. or higher to 400° C. or lower for 30 seconds or more to 30 minutes or less.

19. The method of manufacturing a semiconductor device according to claim 18, wherein the heat treatment is performed at 300° C. or higher to 350° C. or lower for 30 seconds or more to 5 minutes or less.

20. The method of manufacturing a semiconductor device according to claim 15, wherein the pressing is performed with a pressure of 20 MPa or lower.

21. The method of manufacturing a semiconductor device according to claim 20, wherein the pressing is performed with a pressure of 5 MPa or higher to 10 MPa or lower.

22. The method of manufacturing a semiconductor device according to claim 13, wherein the connected conductor is in the form of a ribbon or lead frame.

23. A method of manufacturing a semiconductor device in which a rear surface of a semiconductor chip is disposed on one of Cu conductor patterns that are formed on both surfaces of an insulating substrate, the method comprising the steps of:
joining, to one of the conductor patterns, a Cu metal foam sheet of three-dimensional network having open cells;
inserting a Sn member between the metal foam sheet and the rear surface of the semiconductor chip;
implementing heating at a temperature equal to or higher than a melting point of the Sn member;
bringing about a diffusion reaction between the molten Sn member and the Cu member of the metal foam sheet to join the metal foam sheet and the rear surface of the semiconductor chip together;
dissolving the inserted Sn member by the diffusion reaction; and
forming a CuSn-based alloy and leaving a Cu skeleton of the metal foam sheet of three-dimensional network in a joining base material of the CuSn-based alloy.

24. A method of manufacturing a semiconductor device in which a Cu electric wiring member is disposed on a front surface of the semiconductor chip,
the method comprising the steps of:
joining, to the electric wiring member, a Cu metal foam sheet of three-dimensional network having open cells;
inserting a Sn member between the metal foam sheet and the rear surface of the semiconductor chip;
implementing heating at a temperature equal to or higher than a melting point of the Sn member;
bringing about a diffusion reaction between the molten Sn member and the Cu member of the metal foam sheet to join the metal foam sheet and the rear surface of the semiconductor chip together;
dissolving the inserted Sn member by the diffusion reaction; and
forming a CuSn-based alloy and leaving a Cu skeleton of the metal foam sheet of three-dimensional network in a joining base material of the CuSn-based alloy.

25. The method of manufacturing a semiconductor device according to claim 24, wherein the electric wiring member is in the form of a ribbon or lead frame.

26. The method of manufacturing a semiconductor device according to claim 23, wherein the conductor pattern and the metal foam sheet, or the electric wiring member and the metal foam sheet, are heated or pressed against each other while being heated, and thereby joined directly to each other.

27. The method of manufacturing a semiconductor device according to claim 23, wherein the conductor pattern and the metal foam sheet, or the electric wiring member and the metal foam sheet, are heated or pressed against each other while being heated, and thereby joined to each other by Cu particles.

28. The method of manufacturing a semiconductor device according to claim 23, wherein the conductor pattern and the metal foam sheet, or the electric wiring member and the metal foam sheet, are joined to each other using Ag-based or Cu-based brazing filler metal.

29. A method of manufacturing a semiconductor device in which a rear surface of a semiconductor chip is disposed on one of Cu conductor patterns that are formed on both surfaces of an insulating substrate and in which a Cu electric wiring member is disposed on a front surface of the semiconductor chip, the method comprising the steps of:
joining, to one of the conductor patterns, a first Cu metal foam sheet of three-dimensional network having open cells, and joining, to the electric wiring member, a second Cu metal foam sheet of three-dimensional network having open cells;
inserting a first Sn member between the first metal foam sheet and the rear surface of the semiconductor chip, and also inserting a second Sn member between the second metal foam sheet and the front surface of the semiconductor chip;
implementing heating at temperatures equal to or higher than melting points of the first and second Sn members;
bringing about a diffusion reaction between the first and second molten Sn members and the Cu members of the metal foam sheets, to join the metal foam sheets and the rear and front surfaces of the semiconductor chip together, respectively;
dissolving the first and second inserted Sn members by the diffusion reaction; and
forming a CuSn-based alloy and leaving a Cu skeleton of each of the metal foam sheets of three-dimensional network in a joining base material of the CuSn-based alloy.

30. The method of manufacturing a semiconductor device according to claim 29, wherein each of the metal foam sheets is joined to the conductor pattern and the electric wiring member directly or by using Cu particles or brazing filler metal.

31. A semiconductor device, produced by the method of manufacturing a semiconductor device according to claim 12.
